(19) United States
(12) Patent Application Publication
(10) Pub. No.: US 2010/0132998 A1
(43) Pub. Date: Jun. 3, 2010

(54) Substrate having metal post and method of manufacturing the same

(75) Inventors: Dong Gyu Lee, Gyunggi-do (KR); Jin Won Choi, Seoul (KR); Young Gwan Ko, Seoul (KR); Seon Jae Mun, Gyunggi-do (KR); Tae Joon Chung, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/379,760

(22) Filed: Feb. 27, 2009

(30) Foreign Application Priority Data
Nov. 28, 2008 (KR) 10-2008-0119805

(51) Int. Cl. H05K 1/11; B05D 5/12

(52) U.S. Cl. 174/267; 427/96.4

(57) ABSTRACT

The invention relates to a substrate having a metal post and a method of manufacturing the same, in which a round solder bump part formed on a metal post melts and flows down along a lateral surface of the metal post by being subjected twice to a reflow process, thus forming a solder bump film for preventing oxidation and corrosion of the metal post.

### CROSS REFERENCE TO RELATED APPLICATION

This application claims the benefit of Korean Patent Application No. 10-2008-0119805, filed Nov. 28, 2008, entitled “A Substrate having a Metal Post and a Fabricating Method of the Same”, which is hereby incorporated by reference in its entirety into this application.

### BACKGROUND OF THE INVENTION

1. Field of the Invention

The present invention relates to a substrate having a metal post and a method of manufacturing the same, and more particularly to a substrate having a metal post and a method of manufacturing the same, which realizes a novel configuration capable of preventing oxidation and corrosion while using a simple process.

2. Description of the Related Art With the recent advancement of the electronics industry, there is a demand for increasing performance and functionality of electronic components and reducing the size thereof. Accordingly, high integration, slimness and fine circuit patterning are also required on a substrate for surface mounting components, such as SIP (System in Package), 3D package, etc.

In particular, in techniques for mounting electronic components on the surface of a substrate, a wire bonding process and a flip chip bonding process are utilized for forming electrical connections between a semiconductor chip and a substrate. In the case of the wire bonding process, electronic components must be connected to a PCB using a wire, thus increasing a size of the resulting module and requiring additional processes. Furthermore, the wire bonding process has a limit concerning the realization of a finely pitched circuit pattern. Consequently, these days the flip chip bonding process is predominantly used.

The flip chip bonding process is conducted in such a way as to form external connection terminals (i.e. bumps) each having a size of tens of μm to hundreds of μm on a semiconductor chip using a material such as gold, solder or another metal, flip over the semiconductor chip having the bump thereon to cause the surface thereof to face the substrate, and mounting the semiconductor chip on the substrate, unlike the mounting operation based on wire bonding.

In order to meet the demands of circuit patterns having ultra-file pitch, the flip chip bonding process is being developed into a structure having a metal post. Utilization of the metal post is attracting a lot of attention since it enables problems concerning the realization of finely pitched circuit patterns to be overcome, and ensures an easy packaging operation and improved heat dissipation.

FIG. 1 is a cross-sectional view of a conventional PCB having metal posts which are used in a flip chip bonding process, and FIG. 2 is a cross-sectional view showing oxide film and recesses occurring in the PCB shown in FIG. 1.

As shown in FIG. 1, the conventional PCB 10 having metal posts comprises a base substrate 12 having connecting pads formed thereon, a solder resist layer 16 formed on the base substrate 12 which has openings through which the connecting pads 14 are exposed, metal posts 18 formed on the connecting pads 14, and solder bumps 20 formed on the metal posts 18.

Unfortunately, the conventional PCB 10 having metal posts has the disadvantages below.

In the related art, since lateral surfaces of the metal posts 18 are exposed to air, the lateral surfaces are oxidized or corroded by the action of air or chemicals used in the process, thus permitting an oxide film 18a to form thereon. As a result, the oxide film 18a acts as electrical resistance and decreases physical strength of the metal posts 18.

In addition, the related art has another problem in that the solder bumps 20 are dissolved by chemicals used in the process. More specifically, chemicals such as strong acid and base, which are used in the course of the process, react with the solder bumps 20, and thus the surfaces of the solder bumps 20 are partially dissolved and eliminated. Consequently, the dissolution of the solder bumps results in formation of recesses 20a which permits the upper surfaces of the metal posts 18 to be exposed therethrough and which causes formation of recesses like craters. This hinders provision of solder bumps 20 having even heights, thus deteriorating the reliability of the connection.

In order to solve the above problems, there has been proposed a PCB having metal posts which are provided at the lateral surface with oxidation-inhibiting caps, respectively. Referring to FIG. 3, another conventional PCB 50 having metal posts is shown.

As shown in FIG. 3, the second conventional PCB 50 comprises a base substrate 52 having connecting pads 54 formed thereon, a solder resist layer 56 formed on the base substrate 52 and having openings through which the connecting pads 54 are exposed, solder bumps 60 formed on the metal posts 58, and oxidation-inhibiting caps 62 made of gold and disposed on lateral surfaces of the metal posts 58.

In other words, the second related art proposed a PCB structure in which the metal posts 58 are provided at lateral surfaces with additional respective oxidation-inhibiting caps 62 for inhibiting oxidation of the metal posts.

Nevertheless, the second conventional PCB 50 having metal posts also has disadvantages in that it requires additional materials and processing for the formation of the oxidation-inhibiting caps 62 and the solder bumps 60 formed on the metal posts 58 still contain recesses formed thereon.

### SUMMARY OF THE INVENTION

Accordingly, the present invention has been made keeping in mind the above problems occurring in the prior art, and the present invention provides a substrate having a metal post and a method of manufacturing the same, which are configured to prevent oxidation and corrosion of the metal post.

Furthermore, the present invention provides a substrate having a metal post and a method of manufacturing the same, which is configured to prevent the occurrence of recesses or pits on a solder bump formed on the metal post.

In an aspect, the present invention provides a substrate including: a base substrate having a connecting pad disposed thereon; a solder resist layer disposed on the base substrate and having an opening through which the connecting pad is exposed; a metal post connected to the connecting pad and protruding upwards from the solder resist layer; and a solder bump disposed on the metal post to surround an external surface including a top surface of the metal post.

The solder bump may include a round solder bump disposed on the top surface of the metal post and a the solder bump film for preventing oxidation disposed on a lateral surface of the metal post.

The round solder bump may have a height 50-70% that of a portion of the metal post protruding upwards from the solder resist layer.

The the solder bump film for preventing oxidation disposed on the lateral surface of the metal post may have a contour identical to the lateral surface of the metal post.

The solder bump film for preventing oxidation disposed on the lateral surface of the metal post may be a constant thickness.

The solder bump film for preventing oxidation may have a thickness that is equal to or less than 5% of a diameter of the round solder bump.

The metal post may include a surface-treated layer disposed thereon.

The surface-treated layer may include one selected from the group consisting of a nickel plating layer, a nickel alloy layer, a nickel plating layer having a palladium plating layer disposed thereon, a nickel plating layer having a gold plating layer disposed thereon, a nickel plating layer having a palladium plating layer and a gold plating layer disposed thereon in this order, a nickel alloy plating layer having a palladium plating layer disposed thereon, a nickel alloy plating layer having a gold plating layer disposed thereon, and a nickel alloy plating layer having a palladium plating layer and a gold plating layer disposed thereon in this order.

In the substrate, a Niₓ—Sn_{y}-based intermetallic compound layer may be disposed on an interface between the surface-treated layer and the round solder bump.

The intermetallic compound layer may have a thickness of 1 μm or less.

In another aspect, the present invention provides a method of manufacturing a substrate, including: (A) preparing a base substrate having a connecting pad thereon, forming a solder resist layer on the base substrate, the solder resist layer having a first opening through which the connecting pad is exposed, and forming a seed layer on the solder resist layer including the first opening; (B) applying photosensitive resist on the solder resist layer including the first opening, and forming a second opening in the photosensitive resist such that the connecting pad is exposed through the second opening; (C) forming a metal post in the second opening to be connected to the connecting pad such that the second opening is partially filled with the metal post; (D) applying solder paste on the metal post in the second opening, subjecting the solder paste to a first reflow process to provide an upper round solder bump part, and removing the photosensitive resist and the seed layer; and (E) subjecting the round solder bump to a second reflow process to provide on a lateral surface of the metal post a the solder bump film for preventing oxidation.

The metal post may be formed such that a height of the metal post is of half a height of the photosensitive resist.

The method may further include, between (C) forming the metal post and (D) applying the solder paste, (C1) forming a surface-treated layer on an upper surface of the metal post.

The surface-treated layer may include one selected from the group consisting of a nickel plating layer, a nickel alloy layer, a nickel plating layer having a palladium plating layer disposed thereon, a nickel plating layer having a gold plating layer disposed thereon, a nickel plating layer having a palladium plating layer and a gold plating layer disposed thereon in this order, a nickel alloy plating layer having a palladium plating layer disposed thereon, a nickel alloy plating layer having a gold plating layer disposed thereon, and a nickel alloy plating layer having a palladium plating layer and a gold plating layer disposed thereon in this order.

In the method, a Niₓ—Sn_{y}-based intermetallic compound layer may be disposed on an interface between the surface-treated layer and the round solder bump.

The intermetallic compound layer may have a thickness of 1 μm or less.

In (D) applying the solder paste, the solder paste may be applied on the metal post such that an upper surface of the solder paste is flush with an upper surface of the photosensitive resist.

The second reflow process may be conducted at a rate of progress which is higher by 20%, compared to that of the first reflow process.

In (E) subjecting the round solder bump to the second reflow process, the round solder bump itself may be of a height which is 50-70% that of a portion of the metal post 116 protruding upwards from the solder resist layer.

The solder bump film for preventing oxidation disposed on the lateral surface of the metal post may have a contour identical to that of the lateral surface of the metal post.

The solder bump film for preventing oxidation disposed on the lateral surface of the metal post may be a constant thickness.

The solder bump film for preventing oxidation may be of a thickness that is equal to or less than 5% of a diameter of the round solder bump.

### BREIF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a conventional PCB having metal posts which are used in a flip chip bonding process;

FIG. 2 is a cross-sectional view showing an oxide film and recesses occurring in the PCB shown in FIG. 1;

FIG. 3 is a cross-sectional view of another conventional PCB having metal posts which are used in a flip chip bonding process;

FIG. 4 is a cross-sectional view of a substrate having metal posts according to an embodiment of the present invention; and

FIGS. 5 to 14 are cross-sectional views showing a sequence of a process of manufacturing a substrate having metal posts, according to an embodiment of the present invention.

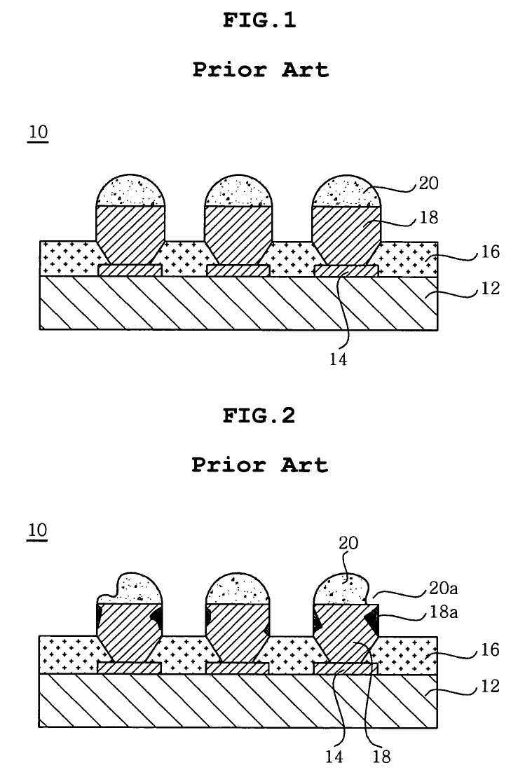

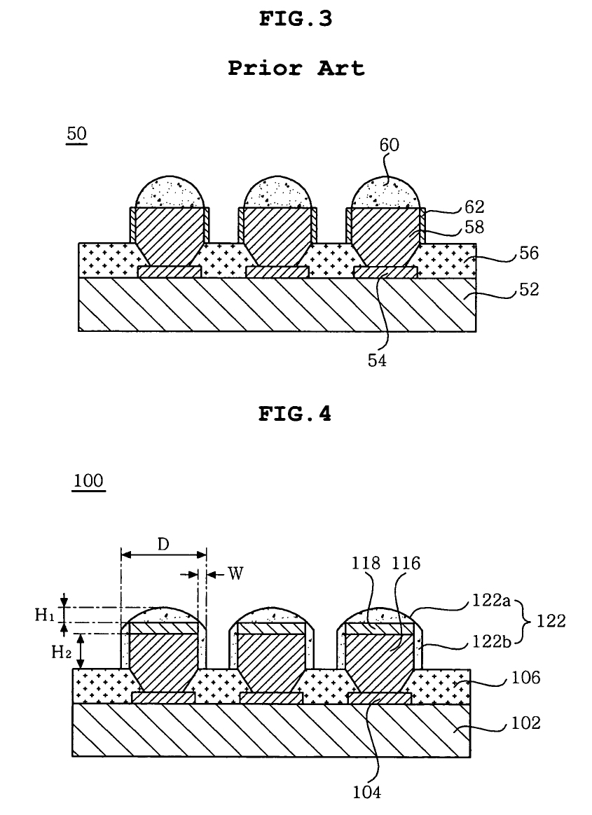

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to best describe the method he or she knows for carrying out the invention.

Concerning the designations of reference numerals, it should be noted that the same reference numerals are used throughout the different drawings to designate the same or similar components. Also, in the description of the present invention, when it is considered that the detailed description of a related prior art may obscure the gist of the present invention, such a detailed description is omitted.

Hereinafter, embodiments of the present invention will be described in greater detail with reference to the following drawings.

Configuration of a Substrate Having Metal Posts

FIG. 4 is a cross-sectional view of a substrate having metal posts according to an embodiment of the present invention. Referring to FIG. 4, the substrate 100 having metal posts, according to the present invention, will now be described.

As shown in FIG. 4, the substrate 100 having metal posts, according to the present invention comprises a base substrate 102, a solder resist layer 106 formed on the base substrate 102, and solder bumps 122 formed on the top surfaces and lateral surfaces of the metal posts 116.

In this context, the base substrate 102 is provided thereon with connecting pads 104, and is provided with the solder resist layer 106 having openings through which the connecting pads 104 are exposed.

The metal posts 116 are intended to function to make pitch of a wiring pattern fine and to ensure high-speed signal transmission between the base substrate 100 and a semiconductor chip, create a distance between semiconductor chips, and provide heat dissipation. The metal posts 116 are connected to the connecting pads 104 and protrude upwards. In this regard, the metal posts 116 may have a cylindrical structure, and may be made of a material such as copper (Cu), nickel (Sn) or gold (Au).

The solder bumps 122 are formed on the corresponding metal posts 116 such that each of them covers the top surface and the lateral surface of the corresponding metal post 116. Specifically, each of the solder bumps 122 is composed of a round solder bump 122a formed on the top surface of the metal post 116 and a solder bump film for preventing oxidation 122b formed on a lateral surface of the metal post 116.

More specifically, the round solder bump 122a is formed into a hemisphere shape and has a height (H₁) which is about 50-70% of the height (H₂) of the metal post 116. The reason for this is because the round solder bump 122a is subjected twice to a reflow process.

Meanwhile, the solder bump film for preventing oxidation 122b is formed on the lateral surface of the metal post 116 to isolate the metal post 116 from the outside, thus inhibiting oxidation caused by air and corrosion caused by chemicals used in the course of process.

In this embodiment, the solder bump film for preventing oxidation 122b is created as a result of reflowing the round solder bump part 122a formed on the metal post 116 thus causing the round solder bump 122a to partially flow down along the lateral surface of the metal post 116. Consequently, the solder bump film for preventing oxidation 122b is formed into the same contour as that of the metal post 116. For example, the solder bump film for preventing oxidation 122b has a cylindrical contour if the metal post 116 is configured to be cylindrical, and the solder bump film for preventing oxidation 122b has the contour of a square column if the metal post 116 is configured to be of the shape of a square column.

In an embodiment, the solder bump film for preventing oxidation 122b may be formed on the lateral surface of the metal post 116 such that it has a constant thickness.

In this regard, the solder bump film for preventing oxidation 122b has a thickness as thin as possible as long as the solder bump film for preventing oxidation 122b isolates the metal post 116 from the outside and it does not induce interference between the solder bump film for preventing oxidation 122b and the adjacent metal posts 116 which hinders realization of a wiring pattern having a fine pitch. For example, the thickness W of the solder bump film for preventing oxidation 122b may be equal to or less than about 5% of a diameter D of the round solder bump 122a.

Furthermore, a surface-treated layer 118 may be formed on the metal post 116 so as to prevent corrosion and oxidation of the metal post 116.

In this embodiment, the surface-treated layer 118 is of a thin thickness and is made of nickel (Ni) plating or nickel alloy plating. Additionally, the surface-treated layer 118 may further include a palladium (Pd) plating layer, a gold (Au) plating layer, or a combination of a palladium (Pd) plating layer and a gold (Au) plating layer which is formed on the nickel plating layer or the nickel alloy plating layer. In the case of the combination of a palladium (Pd) plating layer and a gold (Au) plating layer, the palladium (Pd) plating layer and the gold (Au) plating layer are formed on the underlying layer in this order.

At this point, the surface-treated layer 118 is bound to the round solder bump 122a of tin (Sn)-based so that a Niₓ—Sn_{y}-based intermetallic compound layer (IMC layer) is formed on the interface therebetween. The intermetallic compound layer may have a thickness of about 1 μm or less.

Process of Manufacturing a Substrate Having Metal Posts

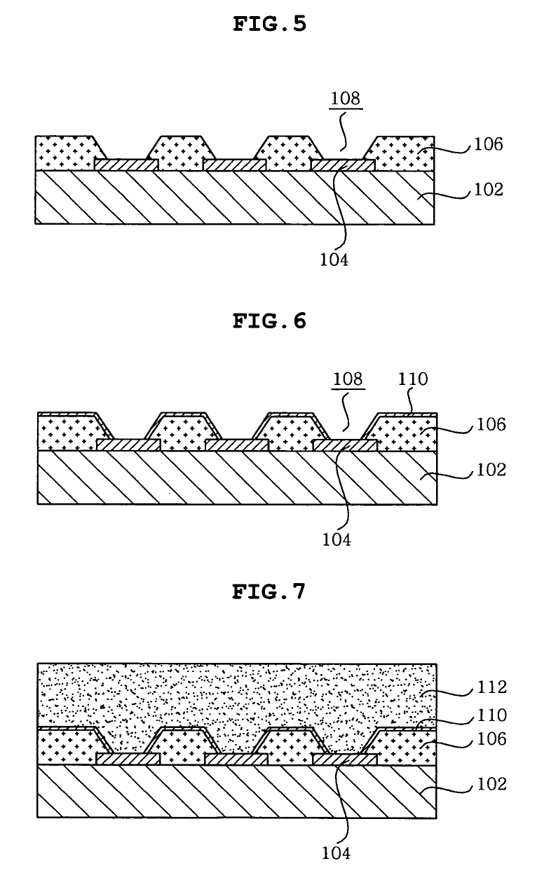

FIGS. 5 to 14 are cross-sectional views showing the sequence of a process of manufacturing a substrate having metal posts, according to an embodiment of the present invention. Referring to the drawings, the process of manufacturing a substrate 100 having metal posts will be described below.

As shown in FIG. 5, a solder resist layer 106 is formed on a base substrate 102 including connecting pads 104 thereon, and then first openings 108 are formed in the solder resist layer 106 to allow the connecting pads 104 to be exposed. At this point, the first openings 108 may be formed through a machining process such as LDA (Laser Direct Ablation) or through an exposure/development process using ultraviolet.

Subsequently, as shown in FIG. 6, a seed layer 110 is formed on the solder resist layer 106 including the openings 108.

At this time, the seed layer 110 is formed through an electroless plating process or a sputtering process. In this regard, the electroless plating process may be conducted by adopting a typical deposition technique using a catalyst composed of a cleanet procedure, a soft etching procedure, a pre-catalyst procedure, a catalyst treating procedure, an accelerator procedure, an electroless plating procedure and an antioxidation treatment procedure, and thus detailed description thereof which is well known in the art is omitted.

Thereafter, as shown in FIG. 7, photosensitive resist 112 is applied to the seed layer 110.

The photosensitive resist 112 may be made of high heat-resistance dry film so as to endure a reflow process which is conducted at a high temperature of 260° C. or higher, and may have a thickness of 60 μm or more for the formation of post bumps having an appropriate height.

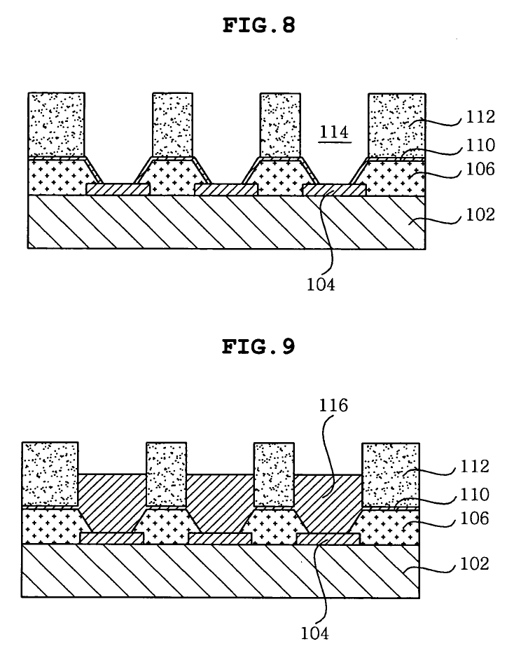

As shown in FIG. 8, second openings 114 are formed in the photosensitive resist 112 through exposure and development processes so as to allow the connecting pads 104 to be exposed therethrough.

At this point, the openings are formed in a manner such that a mask pattern (not shown) is placed on the photosensitive resist 112 such that the remaining area of the photosensitive resist 112 except for the areas located on the connecting pads 104 is exposed through the mask pattern, the exposed area of the photosensitive resist 112 is exposed to ultraviolet radiation, and then the areas of the photosensitive resist 112 which are located on the connecting pads 104 and are not exposed to the ultraviolet are etched and removed using a developing solution such as sodium carbonate (Na₂CO₃) or potassium carbonate (K₂CO₃).

Thereafter, as shown in FIG. 9, metal posts 116, which are connected to the connecting pads 104, are formed in the openings 114 such that each of the second openings 114 is partially filled with the metal post 116.

At this time, the metal posts 116 may be formed through a plating process, and a height of the metal posts 116 may be about 50% of the thickness of the photosensitive resist 112 deposited on the solder resist layer 106.

The metal posts 116 may be made of copper (Cu), nickel (Ni), tin (Sn), gold (Au) or the like.

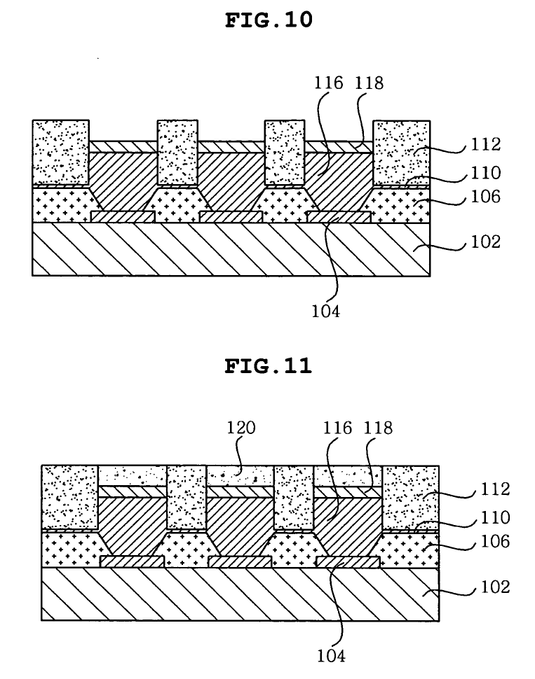

As shown in FIG. 10, a surface-treated layer 118 is formed on the top surfaces of the metal posts 116.

The surface-treated layer 118 may be made of nickel (Ni) plating or nickel alloy plating. Additionally, the surface-treated layer 118 may further include a palladium (Pd) plating layer, a gold (Au) plating layer, or a combination of a palladium (Pd) plating layer and a gold (Au) plating layer which is formed on the nickel plating layer or the nickel alloy plating layer.

Subsequently, as shown in FIG. 11, solder paste 120 is applied on the surface-treated layer 118 in the openings 114.

At this time, the solder paste 120 is applied such that the surface of the resulting solder paste 120 is flush with the surface of the photosensitive resist 112. Assuming that the surface-treated layer 118 is very thin, a height of the solder paste is equal to a thickness of the portion of the metal posts 116 protruding upwards beyond the solder resist layer 106.

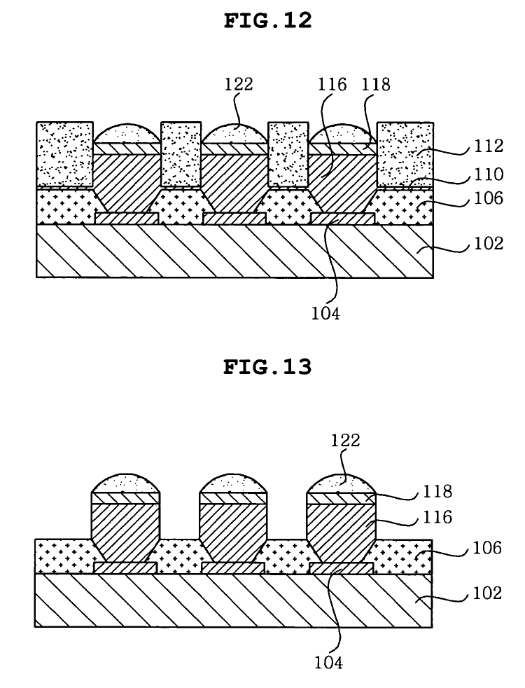

As shown in FIG. 12, the solder paste 120 is subjected to a first reflow process, resulting in round solder bump 122a.

At this point, the round solder bumps 122a are formed only on the top surfaces of the metal posts 116 and have a hemispherical shape, as a result of the melting of the solder paste 120 and then cohesion of the melted solder paste 120 into a hemispherical shape. Furthermore, an organic constituent such as flux in the solder paste 120 is eliminated, and thus the thickness of the solder paste 120 is reduced by about 30% or more.

Thereafter, as shown in FIG. 13, the photosensitive resist 112 is peeled off, and then the seed layer 110 is removed.

At this time, the photosensitive resist 112 is peeled off using a peeling solution such as NaOH or KOH. Specifically, the peeling of the photosensitive resist 112 is obtained by separation of the exposed dry film resist 112 caused by bonding of OH⁻ of the peeling solution to the carboxyl group (COOH⁺).

Meanwhile, the seed layer 110 is removed through a quick etching process using strong base such as NaOH or KOH or a H₂O₂/H₂SO₄ flash etching process.

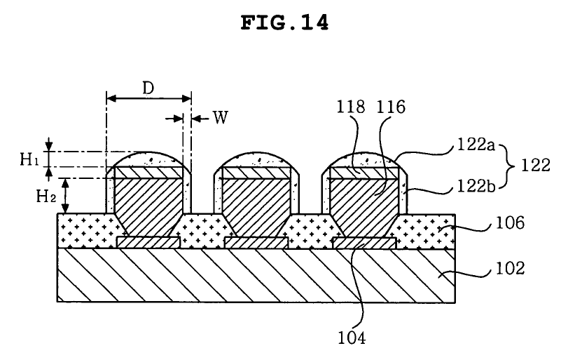

The strong base and acid, which are used in the removal of the photosensitive resist 112 and the seed layer 110, may be problematic because they react with the tin-based round solder bump 122a and cause formation of recesses or pits on the solder bump 122a, thus causing the round solder bump 122a to be of uneven height. However, since the round solder bump 122a will be further subjected to a second reflow process and will be thus formed into a hemispherical shape, as shown in FIG. 14, the present invention does not incur the problem occurring in the related art.

Finally, as shown in FIG. 14, the round solder bump 122a are subjected to the second reflow process so that the solder bump parts melt and flow down along the lateral surfaces of the metal posts 116, resulting in solder bump film for preventing oxidation 122b.

In this embodiment, the second reflow process may be conducted at a rate of progress which is higher by about 20%, compared to that of the first reflow process. The reason why the rate of progress of the second reflow process is set to such a value is as follows. That is, if the rate of progress of the second reflow process is equal to or slower than that of the first reflow process, an excessive amount of solder flows down which may cause formation of recesses on the round solder bump 122a or increase of thickness of the solder bump film for preventing oxidation 122b. On the contrary, if the rate of progress of the second reflow process is higher than the specified rate, the amount of solder which flows down is reduced which may prevent the solder from sufficiently surrounding the entire lateral surface of the metal posts 116.

Furthermore, since the round solder bumps 122a which have been subjected to the second reflow process partially flow down along the lateral surfaces of the metal posts 116, the initial height of the solder bump parts is reduced by about 20%. That is, the solder paste 120, which is charged to be of a height equal to the height of the portion protruding from the solder resist layer 106, is subjected twice to the reflow process and is changed into a round solder bump part 122a. Consequently, the resulting round solder bump 122a has a height which is about 50-70% the height of the portion of the metal post 116.

At this stage, as the round solder bump 122a melts and flows down by being subjected to the second reflow process, the thickness of the solder bump film for preventing oxidation 122b is progressively increased to a predetermined value.

In addition, even if the round solder bump parts 122a react with the strong base and acid used in removing the photosensitive resist 112 and the seed layer 110 and thus have recesses or pits formed thereon, the round solder bump parts 122a having the recesses or pits are again changed into the desired round shape.

As a result of the manufacturing process described above, the substrate 100 having metal posts, which is capable of preventing oxidation of the metal posts 116 and occurrence of recesses on the round solder bump 122a, is prepared.

According to the present invention, since the metal post is provided at a lateral surface with the solder solder bump film for preventing oxidation, the present invention has an advantage in that oxidation and corrosion of the metal post is efficiently prevented.

Furthermore, since the solder bump part formed on the lateral surface of the metal post is of a thin thickness, it is possible to realize a wiring pattern having an ultra-fine pitch.

In addition, the present invention has an advantage in that the surface-treated layer is formed on the top surface of the metal post and thus an even, thin intermetallic compound layer is created on the interface between the metal post and the round solder bump part, thus improving reliability of bonding therebetween.

Furthermore, even if recesses or pits are formed on the round solder bump part because of the chemicals used in removing the photosensitive resist and the seed layer, the deformed round solder bump part can be restored to the desired round shape with the aid of the second reflow process.

Although the preferred embodiment of the present invention has been disclosed for illustrative purposes, those skilled in the art will appreciate that Various modifications, additions and substitutions are possible, without departing from the scope and spirit of the invention as disclosed in the accompanying claims. Accordingly, such modifications, additions and substitutions should also be understood to fall within the scope of the present invention.

1. A substrate comprising:
a base substrate having a connecting pad disposed thereon;
a solder resist layer disposed on the base substrate and having an opening through which the connecting pad is exposed;
a metal post connected to the connecting pad and protruding upwards from the solder resist layer; and
a solder bump disposed on the metal post to surround an external surface including a top surface of the metal post.

2. The substrate according to claim 1, wherein the solder bump includes a round solder bump disposed on the top surface of the metal post and a solder bump film for preventing oxidation disposed on a lateral surface of the metal post.

3. The substrate according to claim 2, wherein the round solder bump has a height 50-70% that of a portion of the metal post protruding upwards from the solder resist layer.

4. The substrate according to claim 2, wherein the solder bump film for preventing oxidation disposed on the lateral surface of the metal post has a contour identical to the lateral surface of the metal post.

5. The substrate according to claim 2, wherein the solder bump film for preventing oxidation disposed on the lateral surface of the metal post is a constant thickness.

6. The substrate according to claim 2, wherein the solder bump film for preventing oxidation has a thickness that is equal to or less than 5% of a diameter of the round solder bump.

7. The substrate according to claim 1, wherein the metal post includes a surface-treated layer disposed thereon.

8. The substrate according to claim 7, wherein the surface-treated layer includes one selected from the group consisting of a nickel plating layer, a nickel alloy layer, a nickel plating layer having a palladium plating layer disposed thereon, a nickel plating layer having a gold plating layer disposed thereon, a nickel plating layer having a palladium plating layer and a gold plating layer disposed thereon in this order, a nickel alloy plating layer having a palladium plating layer disposed thereon, a nickel alloy plating layer having a gold plating layer disposed thereon, and a nickel alloy plating layer having a palladium plating layer and a gold plating layer disposed thereon in this order.

9. The substrate according to claim 8, wherein a Niₓ—Sn_{y}-based intermetallic compound layer is disposed on an interface between the surface-treated layer and the round solder bump.

10. The substrate according to claim 9, wherein the intermetallic compound layer has a thickness of 1 μm or less.

11. A method of manufacturing a substrate, comprising:
preparing a base substrate having a connecting pad thereon, forming a solder resist layer on the base substrate, the solder resist layer having a first opening through which the connecting pad is exposed, and forming a seed layer on the solder resist layer including the first opening;
applying photosensitive resist on the solder resist layer including the first opening, and forming a second opening in the photosensitive resist such that the connecting pad is exposed through the second opening;
forming a metal post in the second opening to be connected to the connecting pad such that the second opening is partially filled with the metal post;
applying solder paste on the metal post in the second opening, subjecting the solder paste to a first reflow process to provide a round solder bump, and removing the photosensitive resist and the seed layer; and
subjecting the round solder bump to a second reflow process to provide on a lateral surface of the metal post a solder bump film for preventing oxidation.

12. The method according to claim 11, wherein the metal post is formed such that a height of the metal post is of half a height of the photosensitive resist.

13. The method according to claim 11, further comprising, between forming the metal post and applying the solder paste, forming a surface-treated layer on an upper surface of the metal post.

14. The method according to claim 13, wherein the surface-treated layer includes one selected from the group consisting of a nickel plating layer, a nickel alloy layer, a nickel plating layer having a palladium plating layer disposed thereon, a nickel plating layer having a gold plating layer disposed thereon, a nickel plating layer having a palladium plating layer and a gold plating layer disposed thereon in this order, a nickel alloy plating layer having a palladium plating layer disposed thereon, a nickel alloy plating layer having a gold plating layer disposed thereon, and a nickel alloy plating layer having a palladium plating layer and a gold plating layer disposed thereon in this order.

15. The method according to claim 14, wherein a Niₓ—Sn_{y}-based intermetallic compound layer is disposed on an interface between the surface-treated layer and the round solder bump.

16. The method according to claim 15, wherein the intermetallic compound layer has a thickness of 1 μm or less.

17. The method according to claim 11, wherein, in applying the solder paste, the solder paste is applied on the metal post such that an upper surface of the solder paste is flush with an upper surface of the photosensitive resist.

18. The method according to claim 11, wherein the second reflow process is conducted at a rate of progress which is higher by 20%, compared to that of the first reflow process.

19. The method according to claim 11, wherein, in subjecting the round solder bump to the second reflow process, the round solder bump itself is of a height which is 50-70% that of a portion of the metal post protruding upwards from the solder resist layer.

20. The method according to claim 11, wherein the solder bump film for preventing oxidation disposed on the lateral surface of the metal post has a contour identical to that of the lateral surface of the metal post.

21. The method according to claim 11, wherein the solder bump film for preventing oxidation disposed on the lateral surface of the metal post is a constant thickness.

22. The substrate according to claim 11, wherein the solder bump film for preventing oxidation is a thickness that is equal to or less than 5% of a diameter of the round solder bump.
